(19) United States
(12) Patent Application Publication
(10) Pub. No.: US 2005/0064683 A1
(43) Pub. Date: Mar. 24, 2005

(54) Method and apparatus for supporting wafers for die singulation and subsequent handling

(76) Inventors: Warren M. Farnworth, Nampa, ID (US); Charles M. Watkins, Eagle, ID (US)

Correspondence Address: TRASK BRITT, P.O. BOX 2550, SALT LAKE CITY, UT, 84110, US

(21) Appl. No.: 10/666,930

(22) Filed: Sep. 19, 2003

(51) Int. Cl. H01L 21/00; H01L 21/31; H01L 21/46; H01L 21/78; B65G 49/07

(52) U.S. Cl. 438/464; 438/460; 414/935

(57) ABSTRACT

A method and apparatus for singulating a semiconductor substrate such as a wafer into individual components are disclosed. The peripheral edge of the substrate (termed the “edge bead ring” or “EBR”) where no components are fabricated is used as a support ring in place of a conventional film frame to support the substrate. The substrate to be diced may be polymer coated or uncoated. If the EBR is of insufficient width to provide a support ring or is discontinuous, a polymer support ring may be formed about the periphery of the substrate. Adhesive-coated tape such as a UV tape is applied to the backside of the substrate and cut to the size of the substrate. The substrate is then cut to singulate components within the peripheral support ring and the singulated components removed from the tape. The remaining support ring and any defective components may be discarded.

### BACKGROUND OF THE INVENTION

1. Field of the Invention

The present invention relates generally to a material handling method and apparatus for singulating semiconductor dice from bulk semiconductor substrates. More particularly, the invention relates to a method and apparatus for holding bulk semiconductor substrates in the form of wafers for singulation and removal of singulated dice therefrom.

2. State of the Art

Semiconductor devices are typically formed on a bulk semiconductor substrate, generally in the form of a wafer, usually of silicon but sometimes of another semiconductor material such as gallium arsenide or indium phosphide. A plurality of semiconductor devices, termed “dice,” is fabricated on each wafer. Fabricating a plurality of individual semiconductor devices on each wafer allows for simultaneous processing, yielding a large number of semiconductor devices at a reduced cost. After fabrication on the wafer, the individual dice must be separated, or singulated, from the wafer for further processing or incorporated into higher-level assemblies.

Commonly used methods of singulation involve placing a wafer on an adhesive-coated polymer tape or film, which is sufficiently dimensioned to cover the backside of the wafer. The tape or film carrying the wafer is held by a frame, known as a film frame. Conventional singulation or dicing machines utilize a film frame coupled to a chuck, which holds the film frame carrying the wafer on the mounting tape or film stretched across the frame. The wafer carried on the tape or film is then cut through the thickness thereof using a saw, a water jet cutting device or a laser beam, without cutting the tape or film, thus separating or singulating the individual semiconductor dice.

In a conventional singulation operation, a wafer mounted on the adhesive side of the mounting tape or film, installed on a film frame and mounted on a chuck, is stabilized by a vacuum applied to the bottom of the mounting tape or film. The semiconductor dice on the wafer are then separated from one another along boundaries defined between adjacent individual semiconductor die locations on the wafer. These boundaries are usually referred to as “streets.” The cutting process cuts along the streets and produces individual semiconductor dice still attached to the tape or film by the adhesive. The tape or film is not cut through and remains intact and attached to the film frame. Following singulation, the wafer and frame are typically washed to remove debris resulting from the singulation process. After singulation is complete, the film frame and wafer are processed to remove individual semiconductor dice from the tape or film, for example, by a pick-and-place apparatus. Further processing typically involves packaging and testing the dice and shipment to end users for installation on a carrier substrate of a higher-level electronic assembly such as a printed circuit board.

Further processing may also include coating the dice to package them and protect against damage during assembly, shipment and use. The protection may involve coating the dice with a polymer coating over a number of sides of each die. Such as coating is often used in chip-scale packaging (CSP). In CSP, a polymer coating may be used to replace conventional packaging such as a transfer-molded encapsulant and provides a packaged semiconductor device that is essentially the same size as a die. CSP is suitable for use with several common semiconductor connection technologies such as, without limitation, tape automated bonding (TAB) and flip chip. Depending on the sensitivity of the die circuitry and the intended environment of use, one or more sides of the die may be coated with polymer for protection. The number of sides which are polymer coated is found in the description “1×, 2×.” 1× refers to a die having one side coated, for example, the active surface of the die. 2× refers to a die having two sides coated. 0× denotes an uncoated die. The maximum number of sides of a cuboidal die that may be coated is six; hence, 6× denotes a completely coated die. The adhesive tape or film may be stretched to physically separate adjacent dice so that the sides thereof may be coated with polymer while the dice remain adhered to the tape or film.

Additional processing may also include incorporating the dice into higher-level electronic assemblies. The singulated dice may be transferred to holding devices that are compatible with equipment such as pick-and-place machines. A pick-and-place apparatus uses vision technology to recognize the location, orientation and, in some cases, surface features (pin one) of each individual die. The pick-and-place head picks up an individual die using, for example, a vacuum quill and then places the picked die in a container for shipping, in a temporary package for intensive testing to qualify the die as a “Known Good Die” (KGD), on a carrier substrate of a higher-level assembly to which it will be mechanically and electrically connected, or for other processing such as, for example, attachment to a lead frame, wire bonding and transfer molding of a silicon-filled polymer package thereabout. Maps of the carrier substrate or other destination for the die are stored in machine readable memory and delineate where dice should be placed on a corresponding attachment pattern of terminals or lands on the carrier substrate. The maps are preloaded into a memory associated with a computer controlling the pick-and-place machine. Machine vision may also be used to identify the locations of surface features on the die's destination against the map.

The process of singulating a wafer has been well documented in the prior art. U.S. Pat. No. 6,344,402B1 to Sekiya discloses a dicing method using a dicing apparatus. The dicing apparatus includes a chuck table and a frame for holding the wafer to be singulated. The wafer is attached to the frame with adhesive tape. The wafer is cut into small square pieces along the “streets” while held in the frame. After cutting, a volume of air is ejected from the chuck table to the singulated wafer to expand the tape. The expansion spreads the singulated wafer apart by stretching the tape and facilitates further handling.

U.S. Pat. No. 6,245,646B1 to Roberts discloses a film frame for mounting a substrate to mounting tape to retain the substrate to the film frame during the dicing process. A plurality of grooves for receiving a cutting saw extends longitudinally and transversely across the fixture to define die regions. The fixture also includes a plurality of apertures that align with the substrate and with dice to be cut from the substrate. These aligned apertures allow a vacuum to retain the substrate and cut dice in the fixture. Upon completion of dicing, the dice are removed from the fixture.

For most of the semiconductor industry, the standard for wafer size has been 200 mm, because conventional die fabrication technology has limited the size of the wafer. Tolerances in semiconductors are extremely small and require machines capable of operating accurately at very small dimensions with even smaller tolerances. While placing more dice on each wafer potentially increases fabrication efficiency and yield, as the number of dice per wafer increases, so does the opportunity for unacceptable dimensional tolerance buildup. Tolerance buildup refers to the difficulty in holding a series of dimensional measurements within a larger dimensional measurement. Each individual dimensional measurement adds its own tolerances, plus or minus with respect to an ideal value, to the total. The result is an additive series of dimensional measurements that may not add up to a desired overall dimensional measurement. Since each individual dimensional measurement may add tolerances in a departure from ideal values, the dimensional measurements at the end of a sequence of adjacent parts may be significantly affected. This could mean that singulating semiconductor dice at certain locations on a wafer, such as dice at the wafer periphery, may be inaccurate and may possibly result in cutting into a semiconductor die, or leaving an insufficient lateral border adjacent an integrated circuit on the active surface of a die. As noted above, the conventional industry size for semiconductor wafers that yield the greatest number of dice without significant tolerance problems has been approximately 200 mm. However, as the need for semiconductor dice and other electronic components of smaller size and greater capacity has increased, so has the demand to produce such components at ever-decreasing costs. This has led the current trend to increase the size of the wafers from the conventional 200 mm to a larger 300 mm size. Recent advances in processing technology which reduce the aforementioned tolerance problems and increase yields to acceptable levels are rapidly driving wafer sizes to the 300 mm range for commercialization. The 200 mm wafers were attached to an associated film frame that is conventionally about 300 mm in size. However, with the increase in wafer size to 300 mm, the old frames are, thus, no longer suitable for use.

The larger, 300 mm wafer size enables more semiconductor dice to be fabricated at one time, providing greater production efficiency. However, the larger-size wafers have also created handling and processing problems for the semiconductor industry. Larger and heavier film frames are needed to handle the larger wafers. Larger film frames contribute to the handling difficulties, as film frames with wafers are conventionally handled in stacks of twenty-five when moving through the various processing steps. Moving stacks of larger film frames bearing wafers is more difficult since the stacks are heavier and bulkier. Storing the stacks between processing steps also requires more space. Perhaps most significantly, the new larger wafers require larger, conventional film frames that do not fit current conventional handling and processing equipment. The equipment to fabricate semiconductor devices is complex and expensive. Modifying existing equipment to handle larger wafers would require not only larger film frames but also significant and impractical or even impossible changes to the structural components of the equipment where the handling and processing takes place. Thus, there is a need for a method and apparatus for handling the larger-size wafers that is suitable for use with current equipment and processing techniques and solves the potential problem of handling stacks of the wafers using a conventional film frame approach.

### BRIEF SUMMARY OF THE INVENTION

The present invention, in several embodiments, overcomes the above-cited difficulties by providing a method and apparatus for handling wafers larger than 200 mm that eliminates the use of film frames and enables larger-sized wafers, up to 300 mm, to be handled using the same equipment as is currently used for 200 mm wafers. The present invention eliminates the film frame by utilizing the edge bead ring (EBR) of the wafer, a peripheral polymer coating applied to the wafer, or both, as a support ring for wafer handling. In the latter instance, the polymer coating takes the place of, or augments, the EBR.

In embodiments of the present invention, the wafer used may be polymer coated on one or more sides or completely uncoated. When a wafer has been polymer coated, the number of sides coated is documented with a number denoting the number of sides coated 1×-6× as described above. The polymer coating may be used to seal the wafer top, bottom and sides. When a wafer is to be singulated, only the top, bottom and outer periphery of the wafer are available for coating (unless the streets between semiconductor die locations have been scribed) because the sides of the individual semiconductor dice are not yet exposed.

Semiconductor dice are typically square or rectangular, while the wafer is substantially circular (but for the usual flat along a portion of the periphery). The combination of square or rectangular components and a substantially circular wafer results in less than the entire wafer surface being occupied by components to be singulated. The remaining peripheral area of the wafer forms the aforementioned EBR. Where the width of the EBR is too small (i.e., components placed close to the edge, leaving insufficient wafer material to provide a support ring for gripping the edge of the wafer) around a portion or all of the periphery of the wafer, a polymer coating may be extended to surround the periphery of the wafer and, optionally, over the active or backside surface thereof adjacent the periphery so as to increase the diameter and provide a support ring to grip the wafer during the singulation operation and subsequent processing. If an uncoated wafer is to be processed according to the present invention and the EBR width is too small, a support ring of polymer may be formed only about a portion, or all, of the lateral periphery of the wafer.

After peripheral coating, if necessary, an adhesive-coated tape is applied to a surface of the wafer opposite that from which singulation is to be effected. The adhesive-coated tape may comprise a tape coated, for example, on one side with an ultraviolet-sensitive adhesive.

When a taped wafer is ready for singulation, the streets dividing the uncut semiconductor die locations are clearly defined. As previously noted, the peripheral area having no semiconductor dice thereon forms an EBR that may be used to provide support for the wafer. Even if the area forming the EBR is of too small a width to provide a peripheral support ring or is discontinuous to any degree, the method of the invention may be used if the wafer is peripherally coated with a polymer as described above.

In one embodiment of the present invention, singulation is effected by using a laser to make cuts along the streets on the wafer. The singulation process may be carried out utilizing a laser singulation apparatus configured for gripping a 200 mm wafer film frame and which may be used to grip a 300 mm wafer according to the present invention. However, any cutting method used to singulate semiconductor dice may be used with the present invention.

After singulation, the wafer is mounted in a clamshell-type holder for semiconductor dice to be picked therefrom through a central aperture in the top thereof. The singulated dice may be released from the ultraviolet-sensitive adhesive by irradiation through a central aperture in the bottom thereof. Once the singulated semiconductor dice are removed from the frame tape, the remaining EBR and peripheral polymer support ring still adhered to the tape and any unpicked (defective) semiconductor dice resting on the tape may then be discarded.

### BRIEF DESCRIPTION OF THE SEVERAL VIEWS OF THE DRAWINGS

In the drawings, which illustrate what is currently considered to be the best mode for carrying out the invention:

FIG. 1 shows a top view of a wafer with a peripheral polymer coating and EBR.

FIG. 2 is a side sectional view of a wafer mounted to tape and loaded on a singulation apparatus undergoing singulation.

FIGS. 3A and 3B, respectively, depict a top view and a side view of a wafer mounted on tape and ready for singulation.

FIG. 4 is a side sectional view of a singulated wafer mounted for a pick-and-place operation to remove singulated dice therefrom.

### DETAILED DESCRIPTION OF THE INVENTION

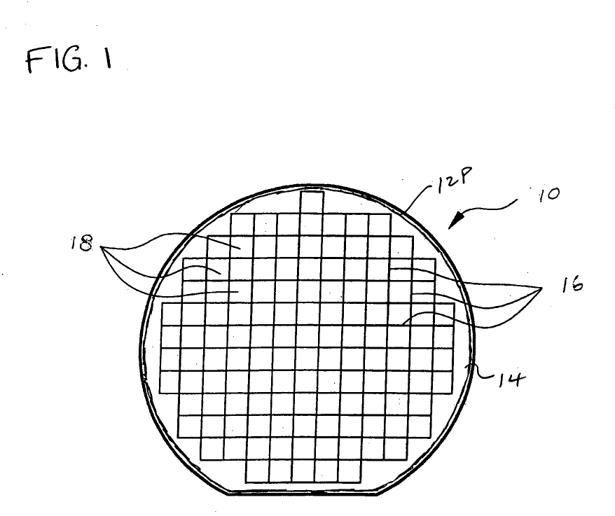

Referring to FIG. 1, 300 mm wafer 10 is depicted with a polymer coating 12P overlying and peripherally adjacent EBR 14 along the outer periphery of wafer 10. Streets 16 extend mutually perpendicularly in the X-Y plane of wafer 10, defining the locations of rectangular semiconductor dice 18 therebetween.

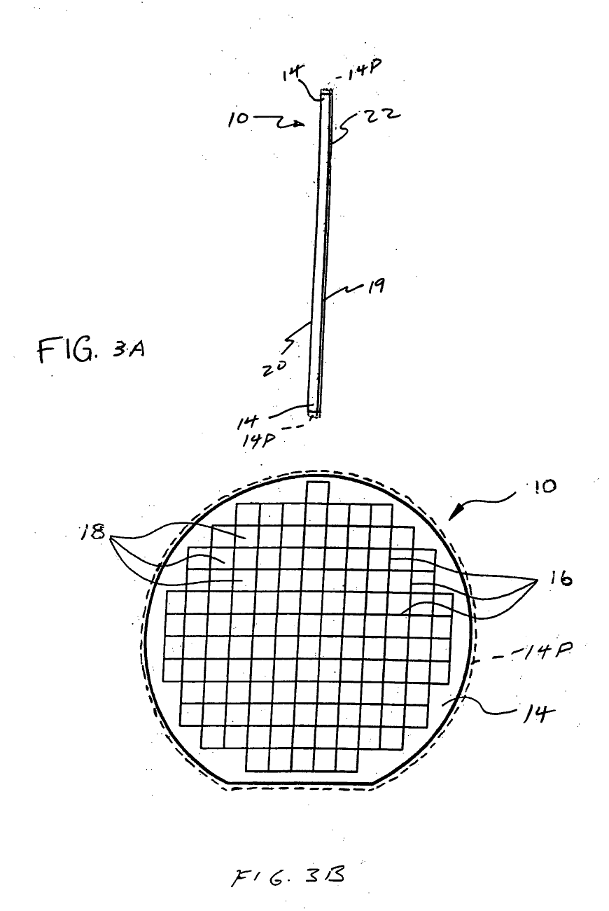

A wafer assembly mounted on tape ready for dicing according to the invention is shown in FIGS. 3A and 3B. The wafer 10 includes a substantially annular EBR 14 and adhesive-coated tape 22 (see FIG. 3A) affixed to the backside 19 of the wafer 10. The lattice-like “street” pattern 16 on active surface 20 for defining and separating semiconductor dice 18 is shown in FIG. 3B. Individual semiconductor dice 18 are shown as still part of wafer 10. No semiconductor dice 18 are located within the area of the EBR 14. The present invention may utilize the EBR 14 as a support ring in place of a film frame, thus permitting a 300 mm wafer to be processed using the same equipment as is presently used with a frame for dicing 200 mm wafers, as the film frame used for 200 mm wafers is of a nominal 300 mm diameter.

Wafers used in accordance with the invention may be polymer coated or uncoated. A wafer with one side coated with polymer is designated as a 1× wafer, with both (active surface and backside) sides and periphery coated, a 3× wafer, etc. The active surface is the surface usually coated on a 1× wafer. An uncoated wafer is designated as a Ox wafer. A wafer which includes scribe lanes extending partially through the wafer and then coated before singulation is termed a 6× wafer, since all of the semiconductor dice 18 eventually singulated from wafer 10 will have at least partial coatings on all six sides thereof. The invention may be used with a polymer-coated wafer or with an uncoated (0×) wafer. If a wafer does not have an EBR wide enough to provide a support ring during the dicing process, such a wafer may still be used in accordance with the present invention if it is peripherally coated with a polymer to slightly increase the diameter of the wafer and build a peripheral polymer support ring 14P thereon, as shown in broken lines in FIGS. 3A and 3B. As noted previously, peripheral polymer support ring 14P may extend over the active surface 20 or backside 19 of wafer 10. The peripheral coat may be formed with mold-type tooling and use a dispensed flowable polymer which is subsequently cured or the peripheral coat may be applied using stereolithography (STL) in the form of a photopolymer cured in place using an energy (laser) beam at specific locations about the periphery. Suitable stereolithography equipment and photopolymers are available from 3D Systems, Inc., of Santa Clara, Calif. STL, as usually practiced, involves using a computer to generate a three-dimensional model of the object to be fabricated. The model is typically generated using computer-aided-design (CAD) software. The model is composed of a large number of relatively thin, superimposed layers, with the completed stack of layers defining the entire object. This model is then used to generate an actual object by building the desired object layer by layer, superimposing the layers upon each other. A wide variety of approaches have been devised for STL object formation. One common approach exemplified by the aforementioned equipment offered by 3D Systems, Inc., involves forming solid structures by selectively curing volumes of a liquid photopolymer or resin material contained within a tank or reservoir. Depending on the liquid material composition, curing may be accomplished by exposure to irradiation with selected wavelengths of light or other electromagnetic radiation, as, for example, when curing a material susceptible to initiation of cross-linking by exposure to ultraviolet (UV) radiation. For the present invention, it is desirable that the EBR or peripheral coating provide about a 3-5 mm wide ring for gripping by a clamshell or other holder around the rim of the wafer. The addition of the peripheral coating ring allows the invention to be used with wafers where the EBR is of insufficient width to be securely gripped. Of course, if a wafer is to be coated on at least one surface thereof in any event, the coating material may be applied by a suitable method to form the peripheral polymer support ring 14P as well. For example, the coating may be applied to at least one of the top and the bottom of the wafer by spin-coating. Spin-coating involves dispensing the polymer on a wafer and spinning the wafer to cause the polymer to spread over the wafer in a uniform manner using centrifugal force, which may also be used to spread the polymer to and over the wafer periphery to form peripheral polymer support ring 14P.

After formation of a polymer support ring 14P if necessary, the semiconductor wafer 10 is then mounted to an adhesive-coated tape 22 using methods standard in the art. The adhesive-coated tape 22 may be attached to the backside of the semiconductor wafer 10 and cut to the size of wafer 10 using a conventional backgrind tape applicator. FIG. 3A shows adhesive-coated tape 22 attached to the backside of the wafer 10. Note that if a peripheral polymer support ring 14P is formed, the adhesive-coated tape 22 extends to the outer periphery thereof as shown in broken lines in FIG. 3A.

In one embodiment of the invention, the wafer 10 is not background to reduce the thickness of the completed semiconductor dice 18. Another embodiment includes backgrinding in order to reduce the thickness of the completed semiconductor dice 18. Generally, the portion of a semiconductor wafer 10 adjacent the backside thereof is not used to form integrated circuitry of the semiconductor dice 18 being fabricated thereon. Backgrinding reduces the height of the semiconductor dice, which reduces the final package size and also reduces the amount of time needed to cut through the wafer 10 during singulation. The front, or active, surface of wafer 10 is typically covered with a tape or film to protect the circuitry from damage or contamination during the backgrinding process.

The adhesive-coated tape 22 applied to the backside of wafer 10 prior to singulation may use a special adhesive which loses adhesive strength when irradiated with a select wavelength of light, normally UV light. Use of the ultraviolet-type tape is desirable since, when irradiated, it loses its adherent properties and thus reduces stress on the dice during a pick-and-place operation. If ultraviolet tape is used for the backgrind tape, the same tape may be applied for convenience as adhesive-coated tape 22 to the backside of the wafer 10 prior to the singulation operation. If conventional backgrind tape is used, an additional, different tape such as UV-sensitive adhesive-coated tape 22 may need to be applied since conventional backgrind tape is not likely to have sufficient strength to support the dicing operation and cannot be prereleased from the semiconductor dice 18 after singulation.

After adhesive tape application, the wafers may be placed in a handling container, commonly known as a “boat.” The boat is configured for handling stacks of conventional 200 mm wafers in frames and may be used to move the tape-mounted 300 mm wafers 10 between processing stations during the singulation and finishing processes.

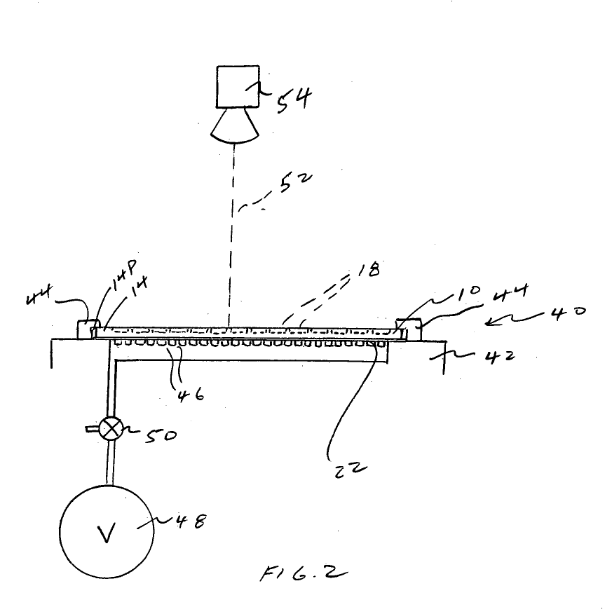

Once an adhesive-coated tape 22 has been applied, the wafers 10 are ready for singulation. A currently preferred embodiment of the invention utilizes thin film up singulation. Thin film up singulation means cutting with the active surface or circuit side of the wafer up. It is also contemplated that embodiments using backgrinding may be singulated with the circuit (active surface) side down, since a UV backgrind tape may be attached on the circuit side of the wafer and the background wafer may then be singulated from the backside, after inversion. In either instance, the tape-coated wafer 10 to be singulated is removed from its boat and loaded onto the chuck of the singulation apparatus as depicted in FIG. 2. The wafer chuck 42 of singulation apparatus 40 supports the wafer 10 and adhesive-coated tape 22 during the singulation process and may include clamps 44 to grip the wafer 10 by pressing the EBR 14 or peripheral polymer support ring 14P, if present, from the sides and over the upwardly facing surface of the wafer 10, in this case depicted as the active surface thereof. Alternatively, the wafer 10 may be maintained on wafer chuck 42 by, for example, an application of a vacuum to adhesive-coated tape 22 through ports 46 selectively connected to vacuum source 48 through valve 50 and opening onto the face of the wafer chuck 42, as shown. The latter approach may provide a larger field for singulation, which may be necessary due to the larger diameter of the 300 mm wafer 10 and consequently closer proximity of semiconductor dice 18 to some portions of the wafer periphery. The singulation apparatus 40 makes precisely positioned cuts following the streets of each wafer. A currently preferred method of singulation is laser ablation. Laser beam 52 is shown in FIG. 2 emanating from laser head 54 to singulate semiconductor dice 18. Laser dicing apparatus are available commercially; one particularly suitable for use with the present invention is offered by XSil Ltd. of Dublin, Ireland, in the form of the Model Xize 200, which is designed for singulation of a 200 mm wafer. However, the present invention is not limited solely to the use of laser dicing machines. For example, water cutting or using a dicing saw may be suitable techniques for use with the present invention.

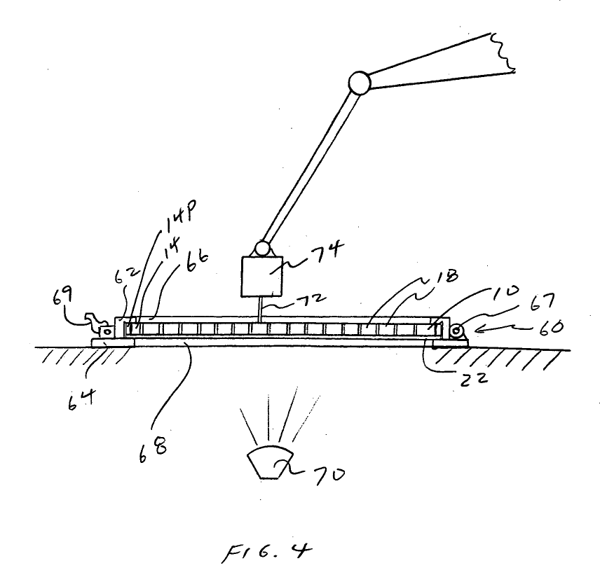

After singulation of semiconductor dice 18 from wafer 10, wafer 10 is again placed in its boat and transferred to a pick-and place apparatus for removal of semiconductor dice 18 therefrom. The pick-and place apparatus may be conventional and sized for a 200 mm wafer held in a film frame. As is conventional, semiconductor dice 18 have been probe-tested to eliminate any obviously defective dice prior to singulation, and those dice appropriately marked. Prior to placement in the pick-and place apparatus, wafer 10 may be loaded into a clamshell-style holder 60 comprising upper and lower portions 62 and 64, respectively, as depicted in FIG. 4. The EBR 14 and peripheral polymer support ring 14P, if present, are gripped between upper and lower portions 62, 64, which respectively define central openings 66 and 68. While clamshell-style holder 60 is depicted as being an assembly having a hinge 67 connecting upper and lower portions 62, 64 at one side and a catch 69 for securing them together opposite the hinge 67, upper and lower portions 62, 64 may be fastened to each other peripherally at several locations using clips, clamps or other suitable fasteners, if desired. The periphery of adhesive-coated tape 22 is covered and masked by lower portion 64, so that when the adhesive thereon is exposed through central opening 68 to UV radiation from source 70, the adhesive is not deactivated to release from EBR 14 and peripheral polymer support ring 14P, while singulated semiconductor dice 18 are released for retrieval through central opening 66 by, for example, a vacuum quill 72 of pick-and-place head 74.

Picked semiconductor dice 18 are then subject to further processing, which may include packaging for shipment to the end user, applying further coatings and structures to complete leads on chip (LOC), chip on board (COB), board on chip (BOC), chip-scale, or other packaging, KGD testing, or direct incorporation into a higher-level device. The EBR 14 or peripheral polymer support ring 14P of wafer 10 remains intact. After all operable semiconductor dice 18 are picked from wafer 10, this leaves the clamshell-style holder 60 containing only defective components on adhesive-coated tape 22 and the EBR 14 or peripheral polymer support ring 14P of the original wafer 10. The defective components, adhesive-coated tape 22 and EBR 14 and peripheral polymer support ring 14P, if present, may be discarded and the clamshell-style holder 40 prepared for another processing cycle.

The invention disclosed herein differs significantly from conventional singulation techniques. Most notable is the elimination of a film frame to hold the wafer during the singulation operation. Since no frame is used with the present invention, the expense of the frame and the time needed to mount the wafer on the frame with tape are eliminated. After conventional singulation of a wafer on a film frame, the adhesive-coated tape or film must be UV exposed for removal from the film frame after the singulated semiconductor dice have been removed. The film frames may then be cleaned to remove any adhesive residue. The method of the present invention eliminates the need for the film frame and film attachment thereto and also eliminates additional steps of film frame exposure after pick-and-place, tape and defective dice removal, frame cleaning, maintenance, and inspection. In addition, elimination of the film frame enables use of dicing frame magazines sized for 200 mm wafers with 300 mm wafers, avoiding the need for new equipment. Further, elimination of the film frame reduces the weight of the product at singulation and reduces the saw chuck size for a given wafer size. In addition, a smaller volume of adhesive-coated tape is employed than if a film frame were used, as the tape is cut to wafer size rather than having to be extended laterally to cover a surrounding surface of a film frame. These advantages of the invention improve output and efficiency, resulting in a more cost-effective singulation process.

Although the present invention has been described in considerable detail with reference to certain preferred versions thereof, other versions are possible. For example, the user may select a different type of tape such as pressure-sensitive tape for the process and the tape may be used to process any types of components formed on semiconductor wafers or other bulk substrates. Therefore, the scope of the appended claims is not limited to the description of the exemplary embodiments disclosed herein.

1. A method for supporting wafers for singulation and pick-and-place, comprising:
providing a semiconductor wafer;
mounting an adhesive-coated tape to a surface of the semiconductor wafer;
singulating the semiconductor wafer into individual components, leaving a ring of material about a periphery thereof; and
removing at least some individual components from the adhesive-coated tape.

2. The method of claim 1, further including gripping the semiconductor wafer by the ring of material during the removing of the at least some individual components.

3. The method of claim 1, further including forming the ring of material from material of the semiconductor wafer.

4. The method of claim 1, further including forming at least a portion of the ring of material from a polymer material disposed about a periphery of the semiconductor wafer.

5. The method of claim 1, further including forming the ring of material in part from material of the semiconductor wafer and in part from a polymer disposed about a periphery of the semiconductor wafer.

6. The method of claim 5, further comprising forming the ring of material from the polymer material by one of spin-coating, stereolithography or molding.

7. The method of claim 1, further comprising backgrinding the semiconductor wafer prior to singulation.

8. The method of claim 7, further comprising mounting the adhesive-coated tape to an active surface of the semiconductor wafer and singulating the semiconductor wafer from a backside thereof after backgrinding.

9. The method of claim 7, further comprising mounting the adhesive-coated tape to a backside of the semiconductor wafer and singulating the semiconductor wafer from an active surface thereof.

10. The method of claim 1, further comprising mounting the adhesive-coated tape to a backside of the semiconductor wafer and singulating the semiconductor wafer from an active surface thereof.

11. The method of claim 1, wherein mounting the adhesive-coated tape comprises mounting a tape bearing a UV-sensitive adhesive thereon.

12. The method of claim 11, further comprising exposing the UV-sensitive adhesive prior to removing the at least some individual components, but for a portion on the adhesive-coated tape extending over the ring of material.

13. The method of claim 1, wherein the semiconductor wafer is singulated using one of laser cutting, water cutting and sawing.

14. The method of claim 1, further comprising discarding the ring of material, any remaining individual components and the adhesive-coated tape after removing the at least some individual components.

15. An in-process semiconductor structure, comprising:
a semiconductor wafer having an adhesive-coated tape adhered to one of an active surface and a backside thereof, the adhesive-coated tape being sized and configured to substantially conform to a periphery of the semiconductor wafer;
wherein the semiconductor wafer includes a plurality of singulated semiconductor dice surrounded by a continuous, peripheral ring of material.

16. The in-process semiconductor structure of claim 15, wherein the continuous, peripheral ring of material comprises material of the semiconductor wafer.

17. The in-process semiconductor structure of claim 15, wherein the continuous, peripheral ring of material comprises a polymer material disposed about the periphery of the semiconductor wafer.

18. The in-process semiconductor structure of claim 15, wherein the continuous, peripheral ring of material comprises material of the semiconductor wafer and a polymer material disposed about the periphery of the semiconductor wafer.

19. The in-process semiconductor structure of claim 15, wherein the adhesive of the adhesive-coated tape comprises a UV-sensitive adhesive.

20. The in-process semiconductor structure of claim 15, further comprising a holder gripping the continuous, peripheral ring of material from thereabove and therebelow and having a central opening exposing the plurality of singulated semiconductor dice and a portion of the adhesive-coated tape extending thereover.

21. The in-process semiconductor structure of claim 20, wherein the adhesive of the adhesive-coated tape comprises a UV-sensitive adhesive.

22. The in-process semiconductor structure of claim 21, wherein the holder includes a peripheral annular portion aligned with and extending over a portion of the adhesive-coated tape overlying the continuous, peripheral ring of material.

23. The in-process semiconductor structure of claim 22, wherein a portion of the UV-sensitive adhesive within the central opening has been exposed to UV radiation to release the plurality of singulated semiconductor dice therefrom.

24. The in-process semiconductor structure of claim 20, wherein the holder is a clamshell-style holder, comprising:
an upper, annular portion having a central opening therethrough;
a lower, annular portion having a central opening therethrough; and
structure for mutually attaching the upper and lower annular portions.

25. A method for processing a semiconductor wafer, comprising:
singulating a semiconductor wafer into individual components and removing at least some singulated individual components without using a film frame.

26. The method of claim 25, wherein the semiconductor wafer is a 300 mm semiconductor wafer and further including handling the 300 mm semiconductor wafer using equipment sized to handle 200 mm semiconductor wafers.

27. The method of claim 26, further including singulating the 300 mm semiconductor wafer using a 200 mm semiconductor wafer saw chuck.

28. The method of claim 26, further including holding the 300 mm semiconductor wafer in a 200 mm semiconductor wafer pick-and-place machine chuck while removing the at least some singulated individual components therefrom.

29. A method of processing a semiconductor wafer, comprising:
singulating a semiconductor wafer into individual components while leaving an uncut peripheral ring of material thereabout.

30. The method of claim 29, further including removing at least some singulated individual components therefrom.

31. The method of claim 30, further including gripping the uncut peripheral ring of material while removing the at least some singulated individual components therefrom.

32. The method of claim 29, further comprising defining the uncut peripheral ring of material from semiconductor material.

33. The method of claim 29, further comprising defining the uncut peripheral ring of material at least in part from a polymer disposed about the semiconductor wafer.

34. The method of claim 29, further comprising defining the uncut peripheral ring of material in part from semiconductor material and in part from a polymer disposed about a periphery of the semiconductor wafer.

35. The method of claim 30, wherein the semiconductor wafer is a 300 mm semiconductor wafer and further including handling the 300 mm semiconductor wafer using equipment sized to handle 200 mm semiconductor wafers.

36. The method of claim 35, further including singulating the 300 mm semiconductor wafer using a 200 mm semiconductor wafer saw chuck.

37. The method of claim 35, further including holding the 300 mm semiconductor wafer in a 200 mm semiconductor wafer pick-and-place machine chuck while removing the at least some singulated individual components therefrom.

38. A method of using a 300 mm semiconductor wafer, including handling the 300 mm semiconductor wafer with equipment sized to handle 200 mm semiconductor wafers.

39. The method of claim 38, further including processing the 300 mm semiconductor wafer with equipment sized to handle 200 mm semiconductor wafers.

40. A wafer holder, comprising:
an upper, annular portion having a central opening therethrough;
a lower, annular portion having a central opening therethrough; and
structure for mutually attaching the upper and lower annular portions.

41. The wafer holder of claim 40, wherein the wafer holder is a clamshell-style holder, and the structure for mutually attaching the upper and lower annular portions comprises a hinge.
